(19) United States
(12) Patent Application Publication
(10) Pub. No.: US 2024/0312858 A1
(43) Pub. Date: Sep. 19, 2024

(54) SEMICONDUCTOR PACKAGE AND METHOD OF MANUFACTURING THE SAME

(71) Applicant: Samsung Electronics Co., Ltd., Suwon-si (KR)

(72) Inventors: Jingfan YANG, Suzhou Industrial Park (CN); Peng ZHANG, Suzhou Industrial Park (CN)

(73) Assignee: Samsung Electronics Co., Ltd., Suwon-si (KR)

(21) Appl. No.: 18/398,926

(22) Filed: Dec. 28, 2023

(30) Foreign Application Priority Data
Mar. 15, 2023 (CN) 202310251278.5

(51) Int. Cl. H01L 23/31; H01L 21/56; H01L 23/00; H01L 25/065

(52) U.S. Cl. CPC H01L 23/3135; H01L 21/56; H01L 23/3128; H01L 23/562; H01L 24/16; H01L 24/81; H01L 25/0652; H01L 25/0657; H01L 2224/16225; H01L 2224/81

(57) ABSTRACT

Provided are semiconductor packages and methods of manufacturing the same. A semiconductor package includes a lower-layer structure including a substrate, a first chip including bumps on an active surface thereof, the first chip being electrically connected to the substrate via the bumps, an upper-layer structure formed of a first molding material, the first molding material covering an inactive surface of the first chip opposite and surrounding at least a portion of a lateral surface of the first chip, the inactive surface of the first chip being opposite to the active surface of the first chip, and a middle-layer structure including at least one interlayer, the at least one inter layer being formed of a second molding material different from the first molding material, the middle-layer structure being between the lower-layer and upper-layer structures and filling a space between the lower-layer and upper-layer structures.

### CROSS-REFERENCE TO RELATED APPLICATION

This application is based on and claims priority under 35 U.S.C. § 119 to the Chinese Patent Application No. 202310251278.5, filed on Mar. 15, 2023, in the Chinese Intellectual Property Office, the disclosure of which is incorporated by reference herein in its entirety.

### BACKGROUND

### 1. Field

Example embodiments of the inventive concepts relate to the field of semiconductor packages, and in particular, to semiconductor packages and/or methods of manufacturing the same.

### 2. Description of the Related Art

In the field of semiconductor packages, a die or a package is generally molded with an epoxy molding material (EMC), or the like, to improve reliability thereof. FIGS. 1, 2, and 3 illustrate methods of improving a warpage issue of a semiconductor package in the related art, respectively. Referring to FIG. 1, when a packaged product is mounted on a printed circuit board (PCB) by a surface-mount technique (SMT), methods such as using a rigid carrier substrate, increasing surface areas of solder balls, and/or the like, are often used in order to improve an issue of an excessive warpage. Referring to FIG. 2, a warpage control structure 1 constituted of a first material 2 of a high coefficient of thermal expansion (CTE), such as an EMC, and a second material 3 of a high modulus, such as a metal, is introduced. The structure 1, which includes the first material 2 and the second material 2, may reduce a warpage occurring in a heating process. Although the technique of FIG. 2 improves the warpage issue, an actual package volume may be affected because the structure 1 has a certain thickness. Referring to FIG. 3, for a die with a bump structure, an EMC fills in a faster rate at a face of the die without bumps than at a face with bumps, which causes occurrence of a filling delay phenomenon under the die and relatively easy happening of packaging-back, thereby generating voids. It can be seen that the above-mentioned shortcomings exist in the related art and such shortcomings are expected to be addressed so as to increase reliability of a semiconductor package.

The above information disclosed in this Background section is only for enhancing the understanding of the background of the present inventive concepts. The above information may contain information that does not form the prior art that is already known in this country to a person of skill in the art.

### SUMMARY

Some example embodiments of the inventive concepts disclose semiconductor packages capable of improving a warpage issue caused by a difference in coefficient of thermal expansion (CTE) and/or a void issue caused by a difference in filling rate of a molding material, and/or manufacturing methods thereof.

According to an example embodiment, a semiconductor package may include a lower-layer structure including a substrate, a first chip including bumps on an active surface thereof, the first chip being electrically connected to the substrate via the bumps, an upper-layer structure formed of a first molding material, the first molding material covering an inactive surface of the first chip and surrounding at least a portion of a lateral surface of the first chip, the inactive surface of the first chip being opposite to the active surface of the first chip, and a middle-layer structure including at least one interlayer, the at least one inter layer being formed of a second molding material different from the first molding material, the middle-layer structure being between the lower-layer structure and the upper-layer structure and filling a space between the lower-layer structure and the upper-layer structure.

In an example embodiment, the first molding material may include a rigid material or a flexible material, and the second molding material may include a flexible material.

In an example embodiment, the second molding material may cover the active surface of the first chip, and surround a remaining portion of the lateral surface of the first chip, the remaining portion of the lateral surface of the first chip being a portion excluding the at least a portion of the lateral surface of the first chip.

In an example embodiment, the at least one interlayer may include a first interlayer and a second interlayer sequentially stacked on the upper-layer structure, the first interlayer may be formed of the second molding material, and the second interlayer may be formed of a third molding material, and the third molding material may include a flexible material.

In an example embodiment, the second molding material may surround a lower portion of the bumps, and the third molding material may surround an upper portion of the bumps.

In an example embodiment, coefficients of thermal expansion (CTEs) of the first molding material, the second molding material and the third molding material may increase sequentially.

In an example embodiment, each of the second molding material and the third molding material may have a modulus lower than a modulus of the first molding material and a modulus of the substrate.

In an example embodiment, the upper-layer structure may have a first thickness, the middle-layer structure may have a second thickness, and a ratio of the first thickness to the second thickness may be configured to control a warpage of the semiconductor package.

In an example embodiment, the first molding material may include the rigid material and may have a first thickness, the second molding material may have a second thickness, the third molding material may have a third thickness, and the first thickness may be less than each of the second thickness and the third thickness.

In an example embodiment, the semiconductor package may further comprise at least one second chip being between the first chip and the substrate and electrically connected to the first chip and the substrate, wherein the second molding material surrounds the at least one second chip.

In an example embodiment, the first molding material may cover both the active surface and an entirety of the lateral surface of the first chip.

In an example embodiment, wherein the first molding material includes the flexible material, the first chip includes a plurality of first chips, and the semiconductor package further includes: a plurality of second chips, stacked on the plurality of first chips, respectively, wherein the plurality of first chips and the plurality of second chips respectively have sizes and stacking forms different from one another to form a complex stacking structure.

According to an example embodiment, a method of manufacturing a semiconductor may include disposing a first chip on a lower-layer structure, the lower-layer structure including a substrate, such that the first chip is electrically connected to the substrate via bumps, which are disposed on an active surface of the first chip, disposing an upper-layer structure on the lower-layer structure by using a first molding material, the first molding material covering an inactive surface of the first chip and surrounding at least a portion of a lateral surface of the first chip, the inactive surface of the first chip being opposite to the active surface of the first chip, and disposing a middle-layer structure by using at least a second molding material different from the first molding material, the middle-layer structure including at least one interlayer formed of at least the second molding material, the middle-layer structure being disposed between the lower-layer structure and the upper-layer structure and filling a space between the lower-layer structure and the upper-layer structure.

In an example embodiment, the first molding material may include a rigid material or a flexible material, and the second molding material may include a flexible material.

In an example embodiment, the first molding material may include the flexible material, and the disposing of the upper-layer structure may include immersing the substrate with the first chip mounted thereon in the first molding material having a fluid state, and curing the first molding material.

In an example embodiment, the first molding material may include the rigid material, and the disposing of the upper-layer structure may include forming a pre-fabricated substrate by using the first molding material, and coupling the first chip to the pre-fabricated substrate through an adhesive material.

In an example embodiment, the disposing of the middle-layer structure may include: immersing the substrate with the upper-layer structure mounted thereon in the second molding material having a fluid state, and curing the second molding material to form a first interlayer on the upper-layer structure, wherein the first interlayer covers the active surface of the first chip, and surrounds a remaining portion of the lateral surface of the first chip, the remaining portion of the lateral surface of the first chip being a portion excluding the at least a portion of the lateral surface of the first chip.

In an example embodiment, the disposing of the middle-layer structure may further include: immersing the substrate with the first interlayer mounted thereon in the third molding material having a fluid state, and curing the third molding material to form a second interlayer on the first interlayer, wherein the third molding material includes a flexible material.

In an example embodiment, the first interlayer may be formed to surround a lower portion of the bumps, and the second interlayer may be formed to surround an upper portion of the bumps.

In an example embodiment, the upper-layer structure may be formed to have a first thickness, the middle-layer structure may be formed to have a second thickness, and a ratio of the first thickness to the second thickness may be formed to control a warpage of the semiconductor package.

In an example embodiment, the first molding material may include the rigid material, the first molding material may be formed to have a first thickness, the second molding material may be formed to have a second thickness, and the third molding material may be formed to have a third thickness, and the first thickness may be less than each of the second thickness and the third thickness.

In an example embodiment, the disposing of the first chip on the lower-layer structure may further include disposing at least one second chip on the substrate, and disposing the first chip on the at least one second chip, and the at least one second chip may be electrically connected to the substrate and the first chip.

In an example embodiment, the immersing may include: immersing the first molding material to cover both the active surface and an entirety of the lateral surface of the first chip.

In an example embodiment, the first chip may include a plurality of first chips, and the forming of the pre-fabricated substrate may include: forming recesses for accommodating the plurality of first chips on the pre-fabricated substrate, and forming, between the recesses, a diversion groove configured to increase a fluidity of a filling material passing therethrough.

In an example embodiment, the first molding material may include the flexible material, the first chip may include a plurality of first chips, and the disposing of the first chip on the lower-layer structure may further include: disposing a plurality of second chips on the substrate; and stacking the plurality of first chips on the plurality of second chips, respectively, wherein the plurality of first chips and the plurality of second chips respectively have sizes and stacking forms different from one another to form a complex stacking structure.

### BRIEF DESCRIPTION OF THE DRAWINGS

Features and advantages of the above and other aspects of the inventive concepts will become apparent from the following detailed description of exemplary embodiments thereof, taken in conjunction with the accompanying drawings. In the drawings, like reference numerals will denote like elements throughout.

FIGS. 1, 2, and 3 illustrate methods of improving a warpage issue of a semiconductor package in the related art, respectively.

FIG. 4 illustrates a semiconductor package according to an example embodiment of the inventive concepts.

FIG. 5 illustrates a semiconductor package according to an example embodiment of the inventive concepts.

FIG. 6 illustrates a semiconductor package according to an example embodiment of the inventive concepts.

FIG. 7 illustrates a semiconductor package according to an example embodiment of the inventive concepts.

FIG. 8 is a schematic view of a substrate having a complex stacking structure thereon before packaged.

FIG. 9 is a schematic view of a semiconductor package having a complex stacking structure according to an example embodiment of the inventive concepts.

FIG. 10 is a schematic view of a semiconductor package having a complex stacking structure according to the related art.

FIG. 11 illustrates a flowchart of a method of manufacturing a semiconductor package according to an example embodiment of the inventive concepts.

FIGS. 12, 13, 14, and 15 illustrate respective steps in FIG. 11, respectively.

FIG. 16 illustrates a flowchart of a method of manufacturing an upper-layer structure of a semiconductor package according to an example embodiment of the inventive concepts.

FIGS. 17 and 18 illustrate respective steps in FIG. 16, respectively.

FIG. 19 illustrates a flowchart of a method of manufacturing an upper-layer structure of a semiconductor package according to an example embodiment of the inventive concepts.

FIG. 20 illustrates a flowchart of a method of manufacturing a middle-layer structure of a semiconductor package according to an example embodiment of the inventive concepts.

FIGS. 21, 22, 23 and 24 illustrate respective steps in FIG. 20, respectively.

FIG. 25 illustrates a flowchart of a method of manufacturing a lower structure of a semiconductor package according to an example embodiment of the inventive concepts.

FIG. 26 illustrates a flowchart of a method of manufacturing a lower structure of a semiconductor package according to an example embodiment of the inventive concepts.

### DETAILED DESCRIPTION

Hereinafter, various example embodiments of the present inventive concepts will be described more fully with reference to the drawings, in which certain example embodiments are illustrated. The present inventive concepts may, however, be embodied in many different forms, and should not be interpreted as being limited to the example embodiments set forth herein. Rather, the disclosed example embodiments are provided such that the description will be thorough and complete, and will convey the scope of the present inventive concepts to those skilled in the art. In the drawings, sizes of layers and regions may be exaggerated for sake of clarity.

For ease of description, spatially relative terms, such as “beneath,” “below,” “lower,” “above,” “upper,” and the like, may be used herein to describe one element's relationship to other elements as illustrated in the drawings. It will be understood that the spatially relative terms are also intended to encompass different orientations of the device in use or operation, in addition to the orientation(s) depicted in the drawings. For example, if the device in the drawings is turned over, an element described as “below” or “beneath” other elements would then be oriented “above” the other elements. Thus, the term “below” can encompass both “above” and “below”. The device may be otherwise oriented (e.g., rotated 90 degrees or at other orientations), and the spatially relative descriptors used herein may be interpreted accordingly.

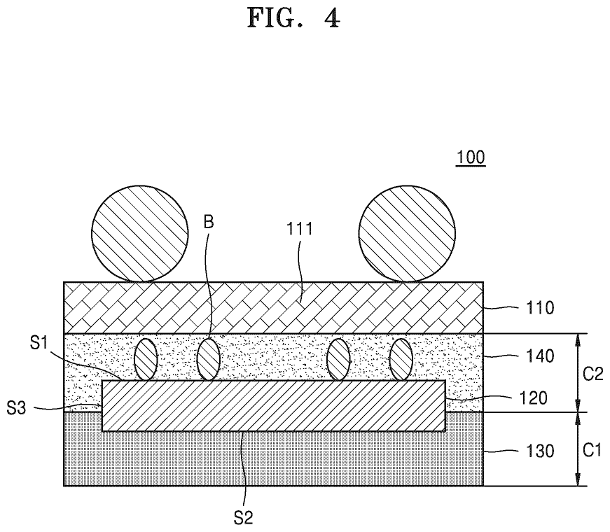

FIG. 4 illustrates a semiconductor package according to an example embodiment of the inventive concepts. Referring to FIG. 4, a semiconductor package 100 includes a lower-layer structure 110, a first chip 120, an upper-layer structure 130, and a middle-layer structure 140. The lower-layer structure 110 includes a substrate 111. The substrate 111 may be any substrate that is commonly used in the art for manufacturing a semiconductor package. The first chip 120 includes bumps B disposed on an active surface S1 thereof. The first chip 120 is electrically connected to the substrate 111 via the bumps B.

The upper-layer structure 130 may be formed of a first molding material. The first molding material covers an inactive surface S2 of the first chip 120 opposite to the active surface S1 of the first chip 120, and surrounds at least a portion of a lateral surface S3 of the first chip 120. Here, the active surface S1 may be a surface on which a circuit pattern is disposed. The inactive surface S2 may be a surface on which a circuit pattern is not disposed. The lateral surface S3 may connect the active and inactive surfaces S1 and S2 with each other.

The middle-layer structure 140 includes at least one interlayer, and the at least one interlayer is formed of at least a second molding material different from the first molding material. The middle-layer structure 140 is disposed between the lower-layer and upper-layer structures 110 and 130, and fills a space between the lower-layer and upper-layer structures 110 and 130.

In a semiconductor package of the related art, because a coefficient of thermal expansion (CTE) of a material for molding is greatly different from that of a substrate, a warpage easily occurs during a heating process. According to some example embodiments of the present inventive concepts, at least one another interposer having a different CTE is introduced between a substrate and a molding material, and the interposer may be used as a buffer layer to absorb a thermal stress of a semiconductor package. This may improve the warpage issue caused by the great difference in coefficient of thermal expansion (CTE) in the semiconductor package, in comparison with a semiconductor package formed with a single molding material.

In addition, for a semiconductor package having a bump structure or a multi-channel structure, a phenomenon of delay in flowing rate of a filling material exists at a bottom of the semiconductor package than at a top thereof, and a void defect is caused accordingly. Semiconductor packages according to some example embodiments of the present inventive concepts may form an upper-layer shielding structure using the first molding material, thereby limiting the difference in flowing rate while the filling of the second molding material, and improving the filling effect.

In an example embodiment, the first molding material may include a rigid material, and the second molding material may include a flexible material. For example, the composition of the first molding material may be an ester or a composite material thereof, or may be an inorganic material such as a metal, a glass, or a ceramic. The composition of the second molding may be an ester or a composite material thereof, but different from the composition of the first molding material. The composition, type, content, and the like, of the second molding material may be different from those of the first molding material so as to adjust the physical properties, for example, an adhesion, a modulus, and/or a coefficient of expansion. For example, the first molding material may be formed using a hard (or rigid) inorganic material, and the second molding material may be formed using an organic material, such that the modulus of the first molding material may be higher than that of the second molding material, thereby increasing the structural rigidity and improving the above-described warpage issue.

In an example embodiment, as shown in FIG. 4, the upper-layer structure 130 may have a first thickness C1, the middle-layer structure 140 may have a second thickness C2, and a ratio of the first thickness C1 to the second thickness C2 may be configured to control a warpage of the semiconductor package 100. For example, the first thickness C1 and the second thickness C2 may have various values according to the respective components of the first and second molding materials. The first thickness C1 may be the same as or different from the second thickness C2. In some example embodiments, the first thickness C1 may be less than the second thickness C2.

In an example embodiment, as illustrated in FIG. 4, the second molding material may cover the active surface S1 of the first chip 120, and surround a remaining portion of the lateral surface S3 of the first chip 120 that excludes the at least a portion of the lateral surface S3 of the first chip 120 surrounded by the upper-layer structure 130 formed of a first molding material. However, the inventive concepts are not limited thereto, and in some example embodiments, the second molding material may not be in contact with the first chip 120.

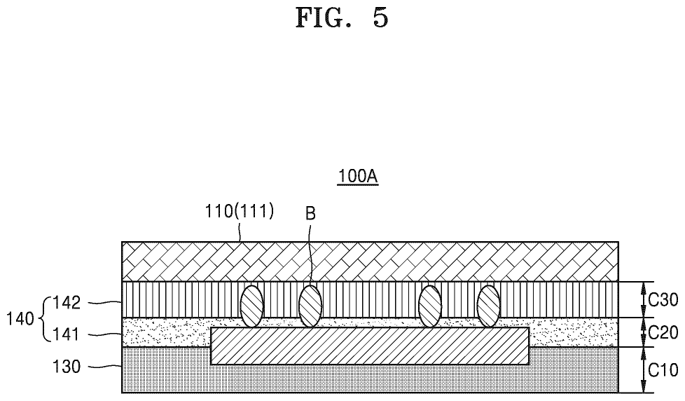

FIG. 5 illustrates a semiconductor package according to an example embodiment of the inventive concepts. As illustrated in FIG. 5, the middle-layer structure 140 of the semiconductor package 100A may include a first interlayer 141 and a second interlayer 142 sequentially stacked on the upper-layer structure 130. The first interlayer 141 may be formed of the second molding material as discussed above. The second interlayer 142 may be formed of a third molding material. The third molding material may include a flexible material.

In an example embodiment, coefficients of thermal expansion (CTEs) of the first molding material forming the upper-layer structure 130, the second molding material forming the first interlayer 141 and the third molding material forming the second interlayer 142 may increase sequentially. In another example embodiment, each of the second molding material and the third molding material may have a modulus lower than a modulus of the first molding material and a modulus of the substrate 111. However, the inventive conception is not limited thereto, a chemical composition and a physical constitution of the upper-layer structure and the middle-layer structure may be chosen according to a specific structure of the semiconductor package so as to adjust the physical properties (e.g., an adhesion, a modulus, and/or a coefficient of expansion) of the first, second and/or third molding material.

In a semiconductor package in the related art, it is difficult to control the property of a package by using a single material because only one kind of molding material is involved. Especially, warpage even delamination failure is easy to happen when a difference on CTE is substantially obvious between the molding material and the substrate. Example embodiments of the inventive conception introduce two or more kinds of molding materials to resolve the above technical problem. Taking a semiconductor package that includes two kinds of molding materials as an example, the molding material used for a middle-layer structure filling a space between an upper-layer structure and a lower-layer structure may have a CTE value between those of the molding materials used for the upper-layer structure and the lower-layer structure. Especially, when using a rigid molding material that thermal deformation is not easy to occur to form an upper-layer structure, the rigid molding material is easy to delaminate from a substrate. In this case, a molding material used for forming a middle-layer structure may have a modulus lower than moduli of the upper-layer structure and a lower-layer structure, and its role is mainly to alleviate internal stress due to differences on warpage forms between the upper-layer structure and the lower-layer structure.

In an example embodiment, as illustrated in FIG. 5, the second molding material used for forming the first interlayer 141 may surround a lower portion of the bumps B, and the third molding material used for forming the second interlayer 142 may surround an upper portion of the bumps B. However, the inventive conception is not limited thereto. The second molding material may not contact the bumps B of the first chip 120. For example, a top surface of the second molding material may be coplanar with a top surface of the first chip 120.

In an example embodiment, the first molding material used for forming the upper-layer structure 130 may include the rigid material and have a first thickness C10. The second molding material used for forming the first interlayer 141 may have a second thickness C20. The third molding material used for forming the second interlayer 142 may have a third thickness C30. The first thickness C10 may be less than each of the second thickness C20 and the third thickness C30. In this case, because the upper-layer structure may be thin, a total thickness of the semiconductor package can be reduced while a rigid of the semiconductor package can be ensured to relieve warpage. Meanwhile, the middle-layer can be formed more thickly so that a problem of insufficient encapsulation can be avoided.

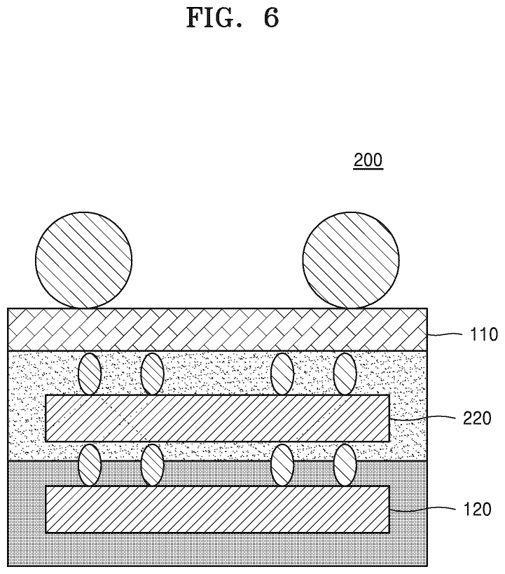

FIG. 6 illustrates a semiconductor package according to an example embodiment of the inventive concepts. Referring to FIG. 6, a semiconductor package 200 may further include at least one second chip 220 disposed between and electrically connected to the first chip 120 and the substrate 111, wherein the second molding material may surround the at least one second chip 220.

In the example embodiment, different from that illustrated in FIG. 4, the first molding material of the semiconductor package 200 illustrated in FIG. 6 may cover the active surface S1, the inactive surface S2, and an entirety of the lateral surface S3 of the first chip 120. In other words, the first molding material may surround the first chip 120. In this case, the bumps B of the first chip 120 may be exposed outside the first molding material, and contact the second molding material and the second chip 220.

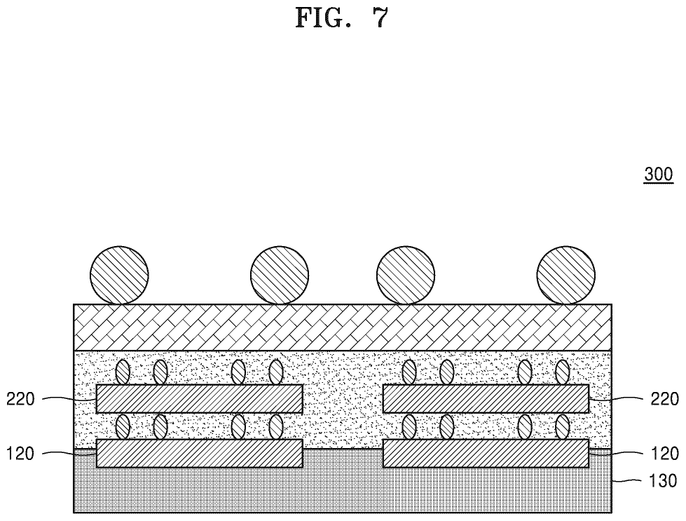

FIG. 7 illustrates a semiconductor package according to an example embodiment of the inventive concepts. Referring to FIG. 7, the first molding material used for forming the upper-layer structure 130 may include a flexible material in a semiconductor package 300. The first chip 120 may include a plurality of first chips 120. A second chip 220 may include a plurality of second chips 220. In this example embodiment, the plurality of first chips 120 may be disposed in a first molding material on the same horizontal plane. The plurality of second chips 220 may be disposed on the first chips 120 one-to-one, and surrounded by a second molding material. Chips in the semiconductor package 300 may have a relative simple stacking structure. However, the inventive concepts are not limited thereto. Hereinafter, a semiconductor package having a complex stacking structure will be described.

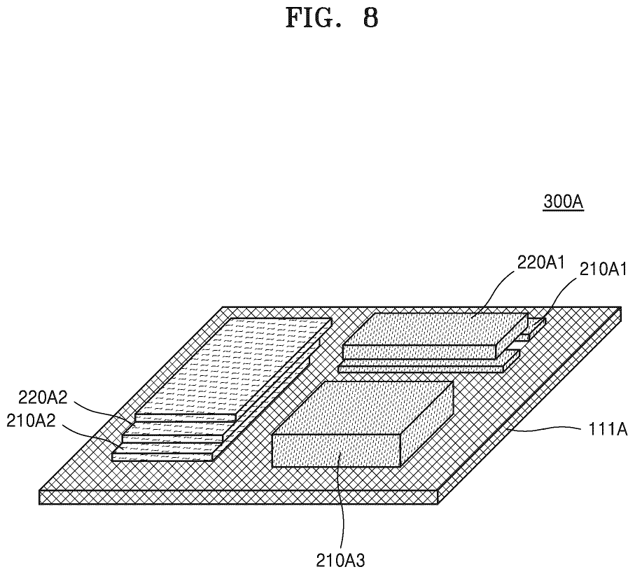

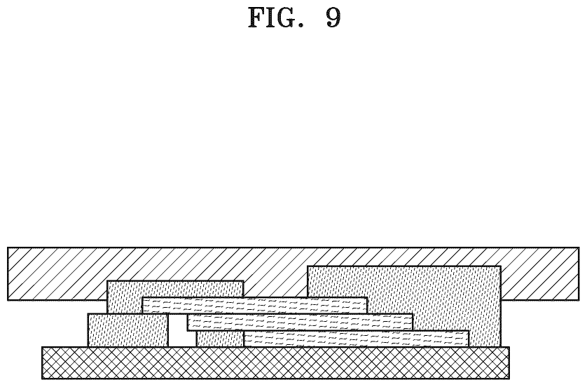

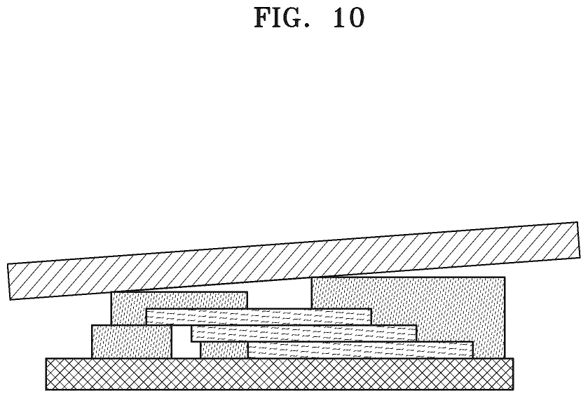

FIG. 8 is a schematic view of a substrate having a complex stacking structure thereon before packaged. FIG. 9 is a schematic view of a semiconductor package having a complex stacking structure according to an example embodiment of the inventive concepts. FIG. 10 is a schematic view of a semiconductor package having a complex stacking structure according to the related art.

Referring to FIG. 8, different from those shown in FIG. 7, a semiconductor package 300A includes: a plurality of first chips 210A and a plurality of second chips 220A stacked on the plurality of first chips 210A, respectively. The plurality of first chips 210A and the plurality of second chips 220A respectively have sizes and stacking forms different from one another to form a complex stacking structure. For example, the plurality of first chips 210A may include first-first chips 210A1, a second-first chip 210A2 and a third-first chip 210A3 that have lengths, widths and thicknesses different from one another. The plurality of second chips 220A may include a first-second chip 220A1 and a second-second chip 220A2 that have lengths, widths and thicknesses different from each other. The first-second chip 220A1 may be stacked on the first-first chips 210A1 to form a first stacking height. The second-second chip 220A2 may be stacked on the second-first chip 210A2 to form a second stacking height. The third-first chip 210A3 may be disposed separately on the substrate 111A without being stacked on any other chips. As illustrated in FIG. 9, a thickness of the third-first chip 210A3 may be greater than the first stacking height. The first stacking height may be greater than the second stacking height. In this case, the semiconductor package 300A according to an example embodiment of the inventive concepts has a complex stacking structure.

In a conventional package structure, hard or rigid material is usually mounted on a top of a package so as to reinforce the package and reduce warpage or deformation, but in such a situation, the top of the package needs to have a flat surface to be combined with the hard or rigid material. For example, as shown in FIG. 10, the conventional package structure fails to encapsulate a complex stacking structure, and is easy to result poor device reliability. On the contrary, the semiconductor package according to the example embodiments of the inventive concepts has characteristics of better encapsulation and coating, and better compositionality and may cover and encapsulate the complex stacking structure. The benefit effect is that: the upper-layer structure formed of a flexible material, and the middle-layer structure formed of at least one molding material and including at least one interlayer, apportion stress inside the package, rather than focus the stress on a combined surface of the hard or rigid material and the package, so that the occurrence of delamination is further reduced, internal chips of the package can be protected, the risk of fracture can be reduced, and the device reliability can be improved.

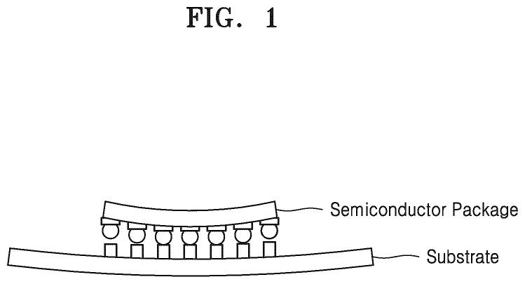

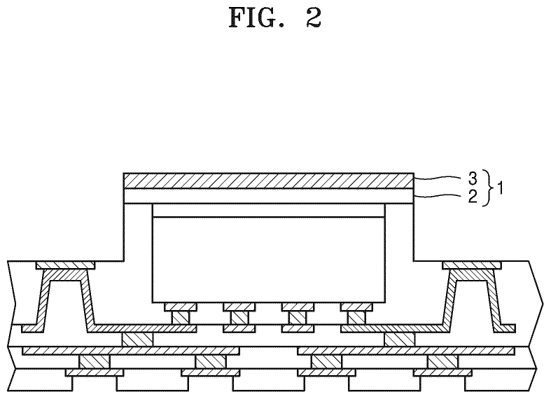

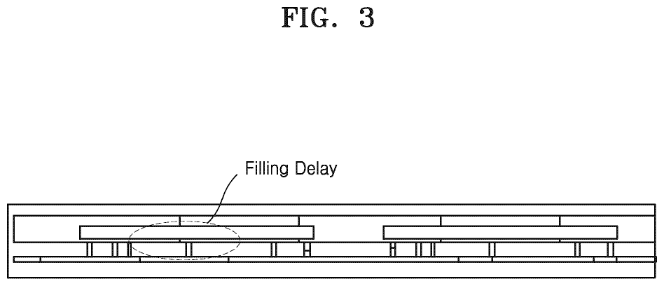

As discussed above, the semiconductor packages according to example embodiments of the inventive concepts have been described by reference to FIGS. 1 to 10. However, the inventive concepts are not limited thereto. In some example embodiments, in addition to the first and second chips, third chips, fourth chips, or more chips may be further disposed on the second chips, and the third chips may be surrounded by a third molding material, and the fourth chips may be surrounded by a fourth molding material, wherein the first to fourth molding materials are different from each other, the second molding material may form a first intermediate layer, the third molding material may form a second intermediate layer, the fourth molding material may form a third intermediate layer, and so on.

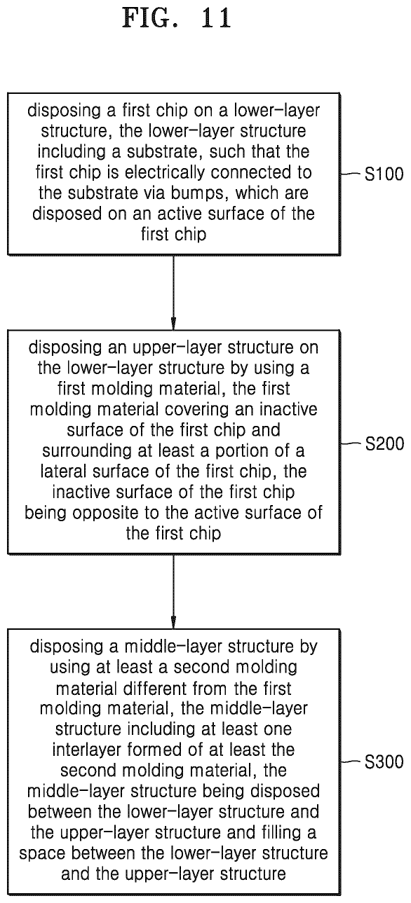

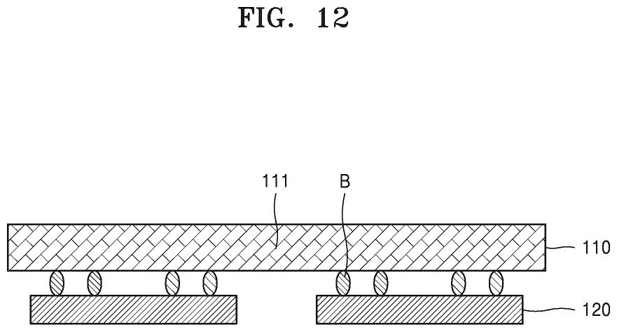

FIG. 11 illustrates a flowchart of a method of manufacturing a semiconductor package according to an example embodiment of the inventive concepts. FIGS. 12, 13, 14, and 15 illustrate respective steps in FIG. 11, respectively. The semiconductor package 100 illustrated in FIG. 4 may be manufactured according to the method illustrated in FIG. 11. The method illustrated in FIG. 11 will be described below with the semiconductor package 100 as an example.

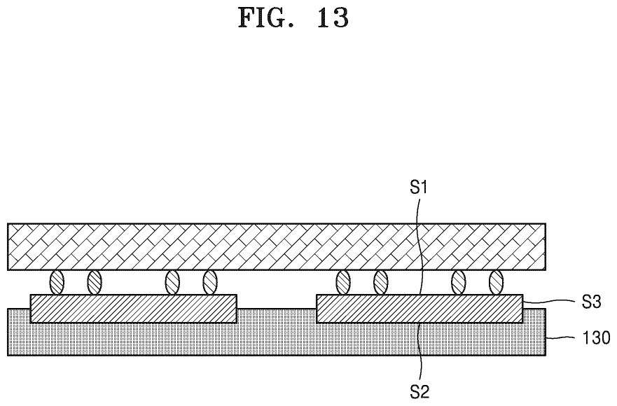

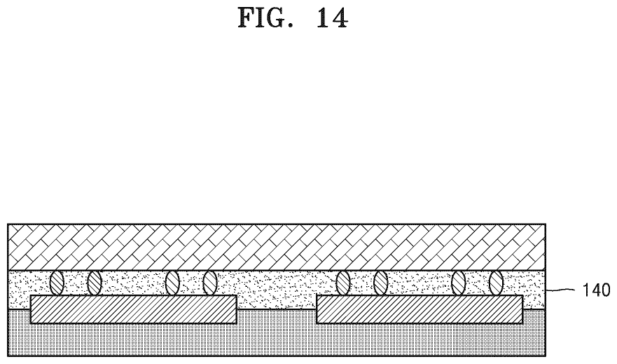

Referring to FIG. 11, in step S100, first chips 120 are disposed on a lower-layer structure 110, as illustrated in FIG. 12. The lower-layer structure 110 may include a substrate 111. The first chips 120 may be electrically connected to the substrate 111 via bumps B disposed on active surfaces S1 thereof. Next, in step S200, an upper-layer structure 130 is disposed on the lower-layer structure 110 by using a first molding material, as illustrated in FIG. 13. The first molding material may cover inactive surfaces S2 of the first chips 120, which are opposite to the active surfaces S1 of the first chips 120, and may surround at least portions of third surfaces S3 of the first chips 120. Next, in step S300, a middle-layer structure 140 is disposed by using at least a second molding material, as illustrated in FIG. 14. The middle-layer structure 140 includes at least one interlayer formed of at least the second molding material. The second molding material is different from the first molding material. The middle-layer structure 140 may be disposed between the lower-layer and upper-layer structures 110 and 130, and may fill a space between the lower-layer and upper-layer structures 110 and 130.

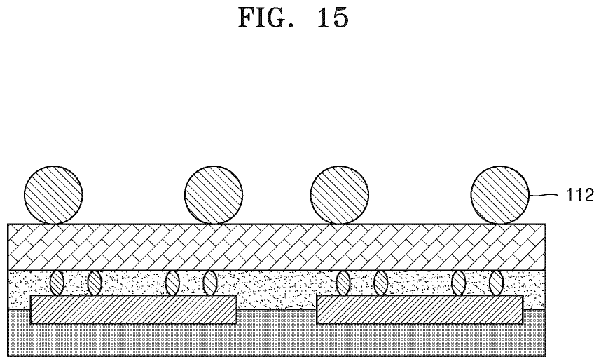

Next, as illustrated in FIG. 15, the upper-layer structure 130 may be thinned through a process, such as grinding, polishing, or the like. Then, pins 112 may be disposed on an outer surface of the substrate 111. Then, a scribing process (e.g., cutting, severing, or singulation process) may be performed on the semiconductor package to form single packages.

In an example embodiment, the first molding material may include a rigid material or a flexible material, and the second molding material may include a flexible material. When the first molding material includes the rigid material, the upper-layer structure of the semiconductor package may be formed by using a process different from that used for forming the same when the first molding material includes the flexible material. For example, when the first molding material includes the rigid material, a surface mounting method may be used for forming the upper-layer structure of the semiconductor package, and when the first molding material includes the flexible material, an immersing method may be used for forming the upper-layer structure of the semiconductor package. Hereinafter, such two kinds of processes will be described, respectively.

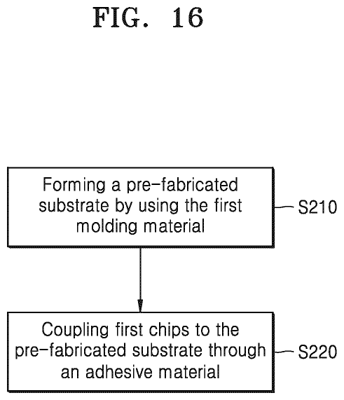

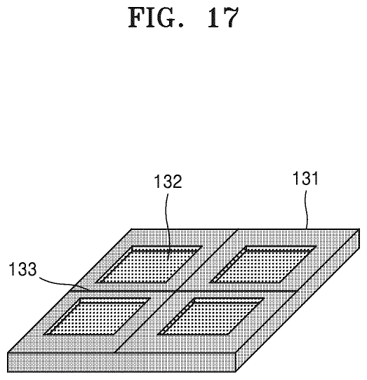

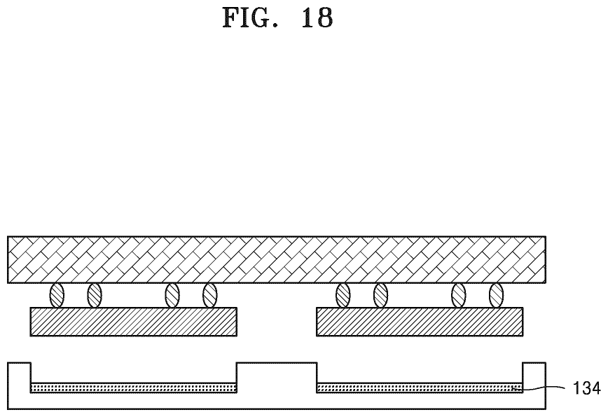

FIG. 16 illustrates a flowchart of a method of manufacturing an upper-layer structure of a semiconductor package according to an example embodiment of the inventive concepts. FIGS. 17 and 18 illustrate steps in FIG. 16, respectively. The semiconductor package 100 illustrated in FIG. 4 may be manufactured according to the method illustrated in FIG. 16. The method of FIG. 16 will be described below with the semiconductor package 100 as an example.

In an example embodiment, the first molding material may include a rigid material, and step S200 shown in FIG. 11 may be performed by using a surface mounting method. The surface mounting method herein may include: in step S210, forming a pre-fabricated substrate 131 by using the first molding material, and in step S220, coupling the first chip 120 to the pre-fabricated substrate 131 through an adhesive material (e.g. an adhesive resin). In an example embodiment, the pre-fabricated substrate 131 may be formed from the first molding material using, for example, impact molding. The pre-fabricated substrate 131 may have a thickness that has a pre-determined value, for example, the first thickness C1 as shown in FIG. 4. The pre-fabricated substrate 131 may form the upper-layer structure 130.

In an example embodiment, the first chip may include a plurality of first chips 120. Step S210 may include forming recesses 132 for accommodating the plurality of first chips 120 on the pre-fabricated substrate 131, and disposing a diversion groove (or a diversion tunnel) 133 between the recesses 132. Depths of the recesses 132 may be determined by an amount thereof in the semiconductor package and/or sizes of the first chips. The diversion groove 133 may increase a fluidity of a filling material, for example, the second molding material, passing therethrough.

In step S220, referring to FIGS. 17 and 18, the adhesive material 134 may be disposed in the recesses 132 of the pre-fabricated substrate 131 before the first chips 120 are placed. A thickness of the adhesive material 134 may be less than the depths of the recesses 132. However, in some example embodiments, the adhesive material 134 may be disposed on the inactive surfaces S2 of the first chips 120, and then the first chips 120 may be placed in the recesses 132 of the pre-fabricated substrate 131.

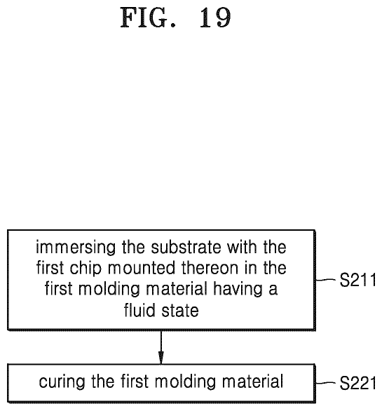

FIG. 19 illustrates a flowchart of a method of manufacturing an upper-layer structure of a semiconductor package according to an example embodiment of the inventive concepts. In an example embodiment, the first molding material may include a flexible material, and step S200 shown in FIG. 11 may be performed by using an immersing method. The immersing method herein may include: in step S211, immersing the substrate 111 with the first chip 120 mounted thereon in the first molding material having a fluid state, and in step S221, curing the first molding material. Specifically, a depth of the immersing can be determined according to a percentage of the first molding material (for example, a volume percentage). The depth of the immersing can be a pre-determined value, for example, the first thickness shown in FIG. 4. The cured first molding material may form the upper-layer structure 130.

Next, step S300 of FIG. 11 may continue to be performed to form the middle-layer structure. In an example embodiment, the upper-layer structure 130 may be formed to have a first thickness C1, the middle-layer structure 140 may be formed to have a second thickness C2, and a ratio of the first thickness C1 to the second thickness C2 may be formed to control a warpage of the semiconductor package 100. Finally, the steps of FIG. 15 are performed to form the whole semiconductor package 100.

The aforementioned surface mounting process and immersing process each have their own advantages and disadvantages. The immersing method is more flexible and has better encapsulation and coating properties, but materials used by the immersing method should be limited to a photo-setting or thermo-setting resin. The surface mounting method is less applicable for a complex stacking structure due to the dissatisfactory accuracy of its prefabricated parts, but more rigid materials, such as ceramics or metals, can be used. Since the immersing method can accurately control a depth of the immersing, below will describe the formation of a middle-layer structure including at least one interlayer and with a specified thickness between an upper-layer structure and a lower-layer structure of the semiconductor package by using the immersing method.

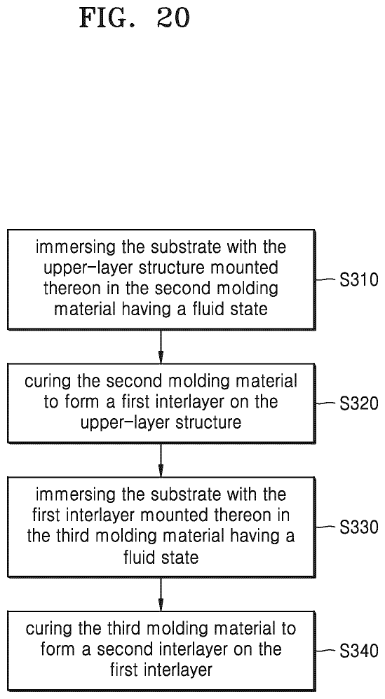

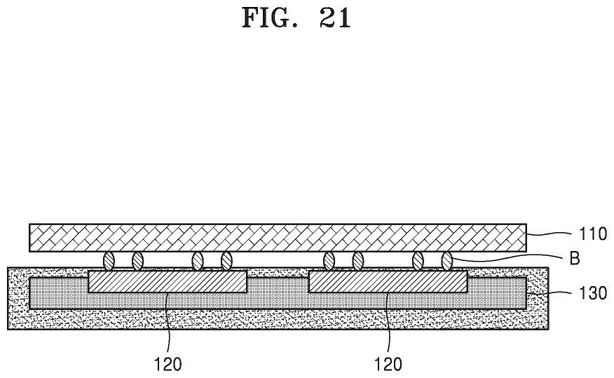

FIG. 20 illustrates a flowchart of a method of manufacturing a middle-layer structure of a semiconductor package according to an example embodiment of the inventive concepts. FIGS. 21, 22, 23 and 24 illustrate respective steps in FIG. 20, respectively. The semiconductor package 100A shown in FIG. 5 can be manufactured according to the method shown in FIG. 20. Below will describe the method of FIG. 20 by taking the semiconductor package 100A as an example.

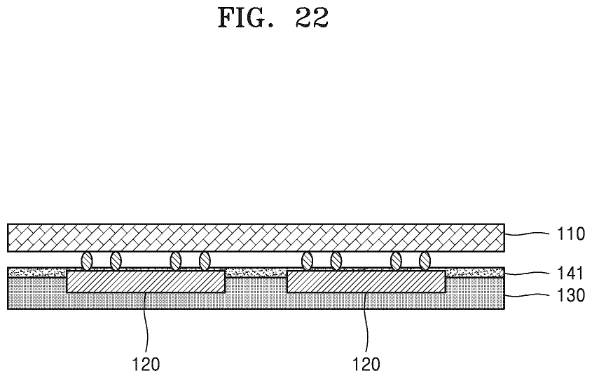

In an example embodiment, step S300 of the disposing of the middle-layer structure may include: step S310, as illustrated in FIG. 21, immersing the substrate 111 with the upper-layer structure 130 mounted thereon in the second molding material having a fluid state, and step S320, as illustrated in FIG. 22, curing the second molding material to form a first interlayer 141 on the upper-layer structure 130. In this example embodiment, the upper-layer structure 130 formed of the first molding material may cover the inactive surface S2 of the first chip 120 opposite to the active surface S1, and surrounds at least a portion of the lateral surface S3 of the first chip 120. The first interlayer 141 formed of the second molding material may cover the active surface S1 of the first chip 120, and surrounds a remaining portion of the lateral surface S3 of the first chip 120.

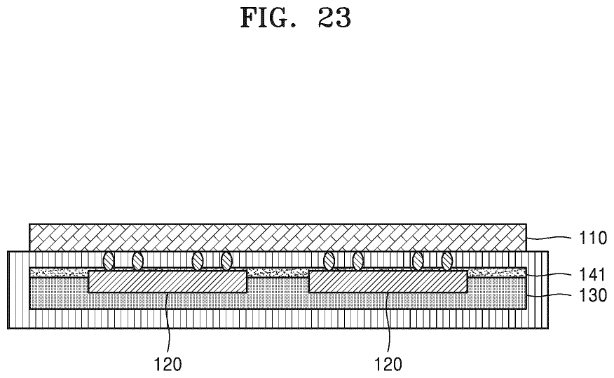

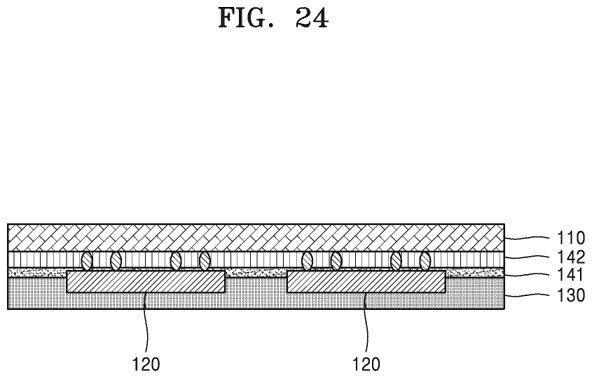

In this example embodiment, step S300 of the disposing of the middle-layer structure may further include: step S330, as illustrated in FIG. 23, immersing the substrate 111 with the first interlayer 141 mounted thereon in the third molding material having a fluid state, and step S340, as illustrated in FIG. 24, curing the third molding material to form a second interlayer 142 on the first interlayer 141, wherein the third molding material may include a flexible material. In addition, a thinning process such as a grind or chemically mechanical polishing process may be performed, after each interlayer has been formed, so as to remove remaining molding materials, thereby forming respective interlayer.

In an example embodiment, as shown in FIG. 5, the first interlayer 141 may be formed with an accurate thickness C20, and the second interlayer 142 may be formed with a accurate thickness C30, when performing the immersing process. The first interlayer 141 may be formed to surround a lower portion of the bumps B, and the second interlayer 142 may be formed to surround an upper portion of the bumps B.

In an example embodiment, when the first molding material of the upper-layer structure 130 is a rigid material, step S200 of forming the upper-layer structure may be performed by a surface mounting method shown in FIG. 16. Together with FIG. 5, in such a situation, the first molding material may be formed with a first thickness C10, the second molding material may be formed with a second thickness C20, and the third molding material may be formed with a third thickness C30. The first thickness C10 may be less than each of the second thickness C20 and the third thickness C30 so that better encapsulation and coating prosperities can be provided for the middle-layer structure, and the rigidity of the upper-layer structure can be combined, so as to relieve warpage of the semiconductor package.

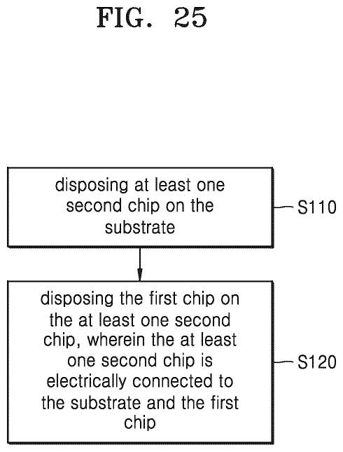

FIG. 25 illustrates a flowchart of a method of manufacturing a lower-layer structure of a semiconductor package according to an example embodiment of the inventive concepts. The semiconductor package 200 illustrated in FIG. 6 or the semiconductor package 300 illustrated in FIG. 7 may be manufactured according to the method illustrated in FIG. 25. The method illustrated in FIG. 25 will be described below with the semiconductor package 200 of FIG. 6 as an example.

Referring to FIG. 25, step S100 of disposing the first chips 120 on the lower-layer structure 110 may include steps S110 and S120. In step S110, referring to FIG. 6, at least one second chip 220 is disposed on the substrate 111. The second chip 220 may have the same structure as that of the first chip 120. The second chip 220 may have bumps B to be electrically connected to the substrate 111. In step S120, referring to FIG. 6, the first chip 120 is disposed on the at least one second chip 220 such that the at least one second chip 220 is electrically connected to the substrate 111 and the first chip 120.

Next, step S200 of FIG. 11 may be subsequently performed to form the upper-layer structure 130 on the lower-layer structure 110 by using the first molding material. Then, step S300 of FIG. 11 may be performed to form the middle-layer structure 140 filling the space between the lower-layer and upper-layer structures 110 and 130 by using the second molding material. In an example embodiment, the first molding material may completely surround the first chips 120, and the second molding material may completely surround the at least one second chip 220. The first molding material may cover portions of the lateral surfaces of the bumps B of the first chips 120, and the second molding material may cover remaining portions of the lateral surfaces of the bumps B of the first chips 120.

Finally, the steps of FIG. 11 may be performed to form an individual semiconductor package 200.

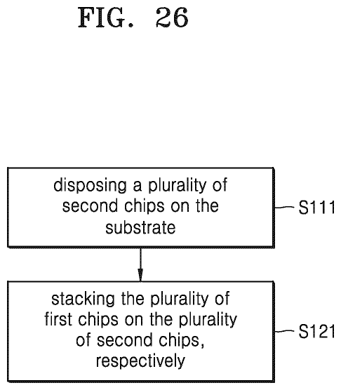

FIG. 26 illustrates a flowchart of a method of manufacturing a lower structure of a semiconductor package according to an example embodiment of the inventive concepts. The semiconductor package 300A shown in FIG. 9 can be manufactured by using the method of FIG. 26. Below will describe the method of FIG. 26 by tacking the semiconductor package 300A as an example.

In an example embodiment, as illustrated in FIG. 9, the first molding material used for forming the upper-layer structure 130 may include a flexible material. The first chip may include a plurality of first chips 120. Step S100 of the disposing of the first chip 120 on the lower-layer structure 110 may further include: step S111, disposing a plurality of second chips 220 on the substrate 111; and step S121, stacking the plurality of first chips 120 on the plurality of second chips 220, respectively. In this example embodiment, the plurality of first chips 120 and the plurality of second chips 220 may respectively have sizes and stacking forms different from one another to form a complex stacking structure. As mentioned above with FIGS. 8 to 10, the method for manufacturing a semiconductor package according to example embodiments of the inventive concepts may realize an encapsulation for a complex stacking structure, such that the occurrence of delamination is further reduced, internal chips of the package can be protected, the risk of fracture can be reduced, and the device reliability can be improved.

In conclusion, in manufacturing methods of the semiconductor packages according to some example embodiments of the present inventive concepts, the first mold structure is first formed, and accordingly, in the subsequent molding processes, the void defect caused by the non-uniformity of the filling rate of the molding material may be improved. In semiconductor packages according to some example embodiments of the inventive concepts, the multilayer mold structure may improve the warpage issue caused due to the great difference in coefficient of thermal expansion in the semiconductor package.

While some example embodiments of the inventive concepts have been illustrated and described herein, it will be apparent to those skilled in the art that various modifications and variations may be made without departing from the spirit and scope of the inventive concepts as defined by the appended claims.

1. A semiconductor package, comprising:
a lower-layer structure including a substrate;
a first chip including bumps on an active surface thereof, the first chip being electrically connected to the substrate via the bumps;
an upper-layer structure formed of a first molding material, the first molding material covering an inactive surface of the first chip and surrounding at least a portion of a lateral surface of the first chip, the inactive surface of the first chip being opposite to the active surface of the first chip; and
a middle-layer structure including at least one interlayer, the at least one inter layer being formed of a second molding material different from the first molding material, the middle-layer structure being between the lower-layer structure and the upper-layer structure and filling a space between the lower-layer structure and the upper-layer structure.

2. The semiconductor package as claimed in claim 1, wherein the first molding material includes a rigid material or a flexible material, and the second molding material includes a flexible material.

3. The semiconductor package as claimed in claim 2, wherein the second molding material covers the active surface of the first chip, and surrounds a remaining portion of the lateral surface of the first chip, the remaining portion of the lateral surface of the first chip being a portion excluding the at least a portion of the lateral surface of the first chip.

4. The semiconductor package as claimed in claim 3, wherein the at least one interlayer includes a first interlayer and a second interlayer sequentially stacked on the upper-layer structure,
the first interlayer is formed of the second molding material, and the second interlayer is formed of a third molding material, and
the third molding material includes a flexible material.

5. The semiconductor package as claimed in claim 4, wherein the second molding material surrounds a lower portion of the bumps, and the third molding material surrounds an upper portion of the bumps.

6. The semiconductor package as claimed in claim 4, wherein coefficients of thermal expansion (CTEs) of the first molding material, the second molding material and the third molding material increase sequentially.

7. The semiconductor package as claimed in claim 4, wherein each of the second molding material and the third molding material has a modulus lower than a modulus of the first molding material and a modulus of the substrate.

8. The semiconductor package as claimed in claim 2, wherein the upper-layer structure has a first thickness, the middle-layer structure has a second thickness, and a ratio of the first thickness to the second thickness is configured to control a warpage of the semiconductor package.

9. The semiconductor package as claimed in claim 4, wherein the first molding material includes the rigid material and has a first thickness, the second molding material has a second thickness, the third molding material has a third thickness, and the first thickness is less than each of the second thickness and the third thickness.

10. The semiconductor package as claimed in claim 2, further comprising:
at least one second chip being between the first chip and the substrate and electrically connected to the first chip and the substrate,
wherein the second molding material surrounds the at least one second chip.

11. The semiconductor package as claimed in claim 10, wherein the first molding material covers both the active surface and an entirety of the lateral surface of the first chip.

12. The semiconductor package as claimed in claim 2, wherein the first molding material includes the flexible material, the first chip includes a plurality of first chips, and the semiconductor package further includes:
a plurality of second chips, stacked on the plurality of first chips, respectively,
wherein the plurality of first chips and the plurality of second chips respectively have sizes and stacking forms different from one another to form a complex stacking structure.

13. A method of manufacturing a semiconductor package, comprising:
disposing a first chip on a lower-layer structure, the lower-layer structure including a substrate, such that the first chip is electrically connected to the substrate via bumps, which are disposed on an active surface of the first chip;
disposing an upper-layer structure on the lower-layer structure by using a first molding material, the first molding material covering an inactive surface of the first chip and surrounding at least a portion of a lateral surface of the first chip, the inactive surface of the first chip being opposite to the active surface of the first chip; and
disposing a middle-layer structure by using at least a second molding material different from the first molding material, the middle-layer structure including at least one interlayer formed of at least the second molding material, the middle-layer structure being disposed between the lower-layer structure and the upper-layer structure and filling a space between the lower-layer structure and the upper-layer structure.

14. The method as claimed in claim 13, wherein the first molding material includes a rigid material or a flexible material, and the second molding material includes a flexible material.

15. The method as claimed in claim 14, wherein the first molding material includes the flexible material, and the disposing of the upper-layer structure includes:
immersing the substrate with the first chip mounted thereon in the first molding material having a fluid state, and
curing the first molding material.

16. The method as claimed in claim 14, wherein the first molding material includes the rigid material, and the disposing of the upper-layer structure includes:
forming a pre-fabricated substrate by using the first molding material; and
coupling the first chip to the pre-fabricated substrate through an adhesive material.

17. The method as claimed in claim 15, wherein the disposing of the middle-layer structure includes:
immersing the substrate with the upper-layer structure mounted thereon in the second molding material having a fluid state, and
curing the second molding material to form a first interlayer on the upper-layer structure,
wherein the first interlayer covers the active surface of the first chip, and surrounds a remaining portion of the lateral surface of the first chip, the remaining portion of the lateral surface of the first chip being a portion excluding the at least a portion of the lateral surface of the first chip.

18. The method as claimed in claim 17, wherein the disposing of the middle-layer structure further includes:
immersing the substrate with the first interlayer mounted thereon in a third molding material having a fluid state, and
curing the third molding material to form a second interlayer on the first interlayer,
wherein the third molding material includes a flexible material.

19. The method as claimed in claim 18, wherein the first interlayer is formed to surround a lower portion of the bumps, and the second interlayer is formed to surround an upper portion of the bumps.

20. The method as claimed in claim 14, wherein the upper-layer structure is formed to have a first thickness, the middle-layer structure is formed to have a second thickness, and a ratio of the first thickness to the second thickness is formed to control a warpage of the semiconductor package.

21-25. (canceled)
